(19) United States
(12) Patent Application Publication
(10) Pub. No.: US 2025/0176163 A1
(43) Pub. Date: May 29, 2025

(54) SEMICONDUCTOR DEVICE

(71) Applicant: SAMSUNG ELECTRONICS CO., LTD., Suwon-si (KR)

(72) Inventors: Sungjoon PARK, Suwon-si (KR); Masayuki Terai, Suwon-si (KR)

(73) Assignee: SAMSUNG ELECTRONICS CO., LTD., Suwon-si (KR)

(21) Appl. No.: 18/827,242

(22) Filed: Sep. 6, 2024

(30) Foreign Application Priority Data
Nov. 24, 2023 (KR) 10-2023-0165373

(51) Int. Cl. H10B 12/00

(52) U.S. Cl. CPC H10B 12/315; H10B 12/05

(57) ABSTRACT

A semiconductor device includes a channel pattern on a substrate and extending in a first direction perpendicular to a surface of the substrate, a gate insulation layer on a sidewall of the channel pattern, the gate insulation layer having an upper surface higher than an uppermost surface of the channel pattern, a first gate electrode on the gate insulation layer and having a first work function, a second gate electrode covering a surface of the first gate electrode, the second gate electrode having a second work function that is greater than the first work function, and a first contact plug on the uppermost surface of the channel pattern, the first contact plug contacting an upper portion of the gate insulation layer, where a lower portion of the first contact plug faces at least a portion of the second gate electrode in a second direction intersecting the first direction.

### CROSS-REFERENCE TO RELATED APPLICATION

This application claims is based on and claims priority under 35 USC § 119 to Korean Patent Application No. 10-2023-0165373, filed on Nov. 24, 2023, in the Korean Intellectual Property Office (KIPO), the disclosure of which is incorporated by reference herein in its entirety.

### BACKGROUND

Example embodiments of the disclosure relate to a semiconductor device including a vertical channel transistor.

For high integration of a semiconductor device, a vertical channel transistor including a channel layer perpendicular to a surface of a substrate may be used in the semiconductor device. A contact plug may be connected to an end of the channel layer of the vertical channel transistor. In the vertical channel transistor, reliability defects in a portion of a gate insulation layer facing both of a contact plug and a gate electrode may occur.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device including a vertical channel transistor.

Additional aspects will be set forth in part in the description which follows and, in part, will be apparent from the description, or may be learned by practice of the presented embodiments.

According to an aspect of an example embodiment, a semiconductor device may include a channel pattern on a substrate, the channel pattern including channel pattern sidewall portions extending in a first direction that is perpendicular to a surface of the substrate and a channel pattern lower portion connecting lower ends of the channel pattern sidewall portions that face each other in a second direction intersecting the first direction, a gate insulation layer on surfaces of the channel pattern sidewall portions and the channel pattern lower portion, the gate insulation layer including gate insulation layer sidewall portions extending in the first direction and a gate insulation layer lower portion connecting lower ends of the gate insulation layer sidewall portions that face each other in the second direction, the gate insulation layer having an upper surface that is higher than an uppermost surface of the channel pattern, a first gate electrode on an inner surface of at least one of the gate insulation layer sidewall portions, the first gate electrode having a first work function, a second gate electrode covering a surface of the first gate electrode, and the second gate electrode having a second work function that is greater than the first work function, and a first contact plug on the uppermost surface of the channel pattern, the first contact plug contacting an upper portion of the gate insulation layer, where an uppermost surface of the second gate electrode is higher than the uppermost surface of the channel pattern.

According to an aspect of an example embodiment, a semiconductor device may include a first conductive layer pattern on a substrate, the first conductive layer pattern extending in a first direction that is parallel to an upper surface of the substrate, a channel patterns on the first conductive layer pattern, the channel pattern including channel pattern sidewall portions extending in a second direction intersecting the first direction and a channel pattern lower portion connecting lower ends of the channel pattern sidewall portions that face each other in the first direction, where a lower surface of the channel pattern contacts the first conductive layer pattern, a gate insulation layer on surfaces of the channel pattern sidewall portions and the channel pattern lower portion, the gate insulation layer including gate insulation layer sidewall portions extending in the second direction and a gate insulation layer lower portion connecting lower ends of the gate insulation layer sidewall portions that face each other in the first direction, the gate insulation layer having an upper surface that is higher than an uppermost surface of the channel pattern, a first gate electrode disposed on an inner surface of at least one of the gate insulation layer sidewall portions, the first gate electrode extending in the second direction, the first gate electrode having a first work function, a second gate electrode covering a surface of the first gate electrode, the second gate electrode extending in the second direction and having a second work function that is greater than the first work function, and a first contact plug on the uppermost surface of the channel pattern, the first contact plug contacting an upper portion of the gate insulation layer, where a height difference between an uppermost surface of the first gate electrode and the uppermost surface of the channel pattern is less than a height difference between an uppermost surface of the second gate electrode and the uppermost surface of the channel pattern.

According to an aspect of an example embodiment, a semiconductor device may include a channel pattern on a substrate, the channel pattern extending in a first direction perpendicular to a surface of the substrate, a gate insulation layer on a sidewall of the channel pattern, the gate insulation layer having an upper surface higher than an uppermost surface of the channel pattern, a first gate electrode on the gate insulation layer, the first gate electrode having a first work function, a second gate electrode covering a surface of the first gate electrode, the second gate electrode having a second work function that is greater than the first work function, and a first contact plug on the uppermost surface of the channel pattern, the first contact plug contacting an upper portion of the gate insulation layer, where a lower portion of the first contact plug faces at least a portion of the second gate electrode in a second direction intersecting the first direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating a semiconductor device according to one or more embodiments;

FIGS. 2 and 3 are cross-sectional views illustrating semiconductor devices according to one or more embodiments;

FIG. 4 is an enlarged cross-sectional view of a portion illustrating a semiconductor device according to one or more embodiments;

FIG. 5 is an enlarged cross-sectional view of a portion illustrating a semiconductor device according to one or more embodiments;

FIGS. 6 to 38 are diagrams illustrating a method of manufacturing a semiconductor device according to one or more embodiments;

FIG. 39 is a cross-sectional view illustrating a method of manufacturing a semiconductor device according to one or more;

FIG. 40 is an enlarged cross-sectional view of a portion illustrating a semiconductor device according to one or more embodiments; and

FIG. 41 is an enlarged cross-sectional view of a portion illustrating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

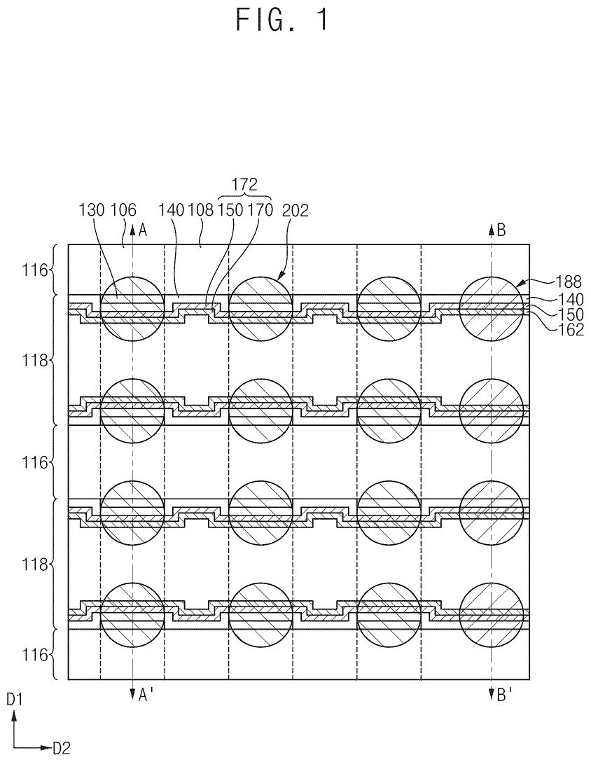

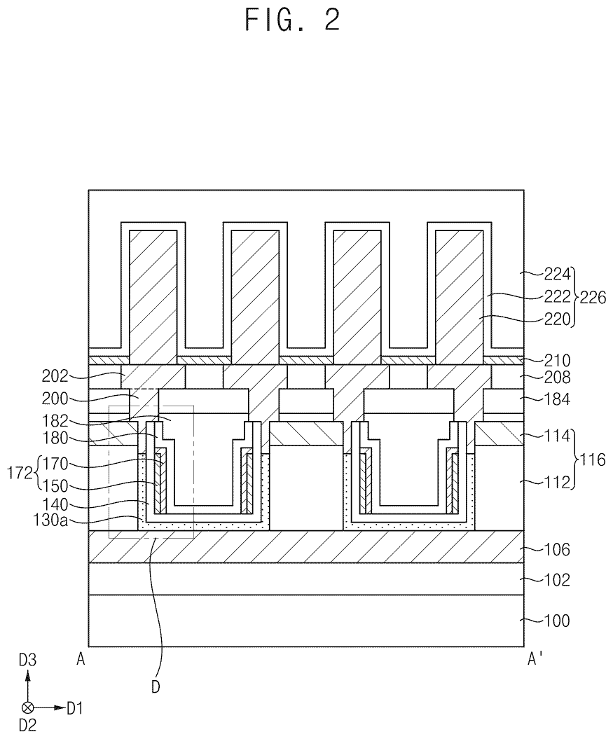

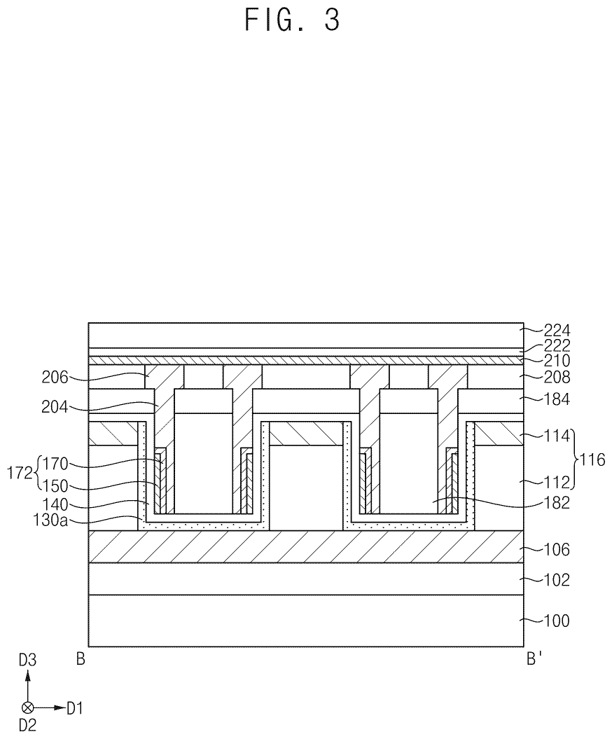

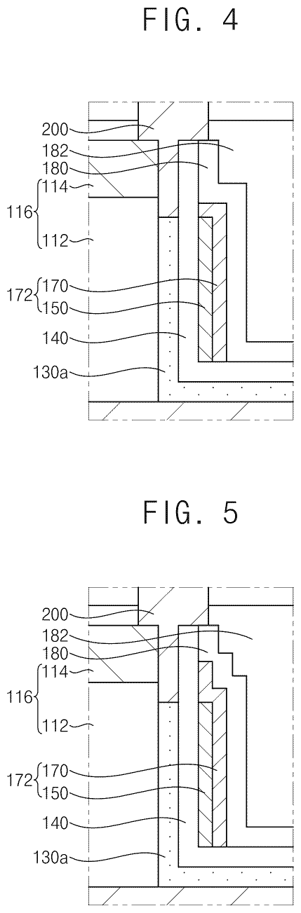

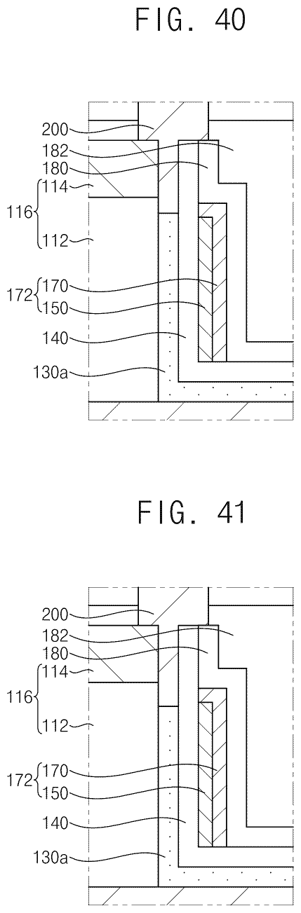

FIG. 1 is a plan view illustrating a semiconductor device according to one or more embodiments. FIGS. 2 and 3 are cross-sectional views illustrating semiconductor devices according to one or more embodiments. FIG. 4 is an enlarged cross-sectional view illustrating a portion of a semiconductor device according to one or more embodiments. FIG. 5 is an enlarged cross-sectional view illustrating a portion of a semiconductor device according to one or more embodiments. FIG. 40 is an enlarged cross-sectional view of a portion illustrating a semiconductor device according to one or more embodiments. FIG. 41 is an enlarged cross-sectional view of a portion illustrating a semiconductor device according to one or more embodiments.

The semiconductor device may be a dynamic random access memory (RAM) (DRAM) device. FIG. 2 is a cross-sectional view taken along line A-A′ in FIG. 1, and FIG. 3 is a cross-sectional view taken along line B-B′ in FIG. 1. FIGS. 4 and 5 are enlarged cross-sectional views of a portion corresponding to D in FIG. 2. For ease of description, components formed on the second conductive layer pattern may be omitted in FIG. 1.

Referring to FIGS. 1 to 3, the semiconductor device may include a first conductive layer pattern 106, a mold insulation structure 116, a channel pattern 130a, a gate insulation layer 140, a first gate electrode 150, a second gate electrode 170, a first contact plug 200, a second contact plug 204, a second conductive layer pattern 202, a third conductive layer pattern 206, and a capacitor 226.

The semiconductor device may further include a first lower insulation layer 102, a capping insulation pattern 180, a buried insulation pattern 182, a first insulation layer 184, a second insulation pattern 208, and a first etch stop layer 210.

In one or more embodiments, the semiconductor device may include a vertical channel transistor formed on a channel pattern 130a including an oxide semiconductor.

The first lower insulation layer 102 may be formed on the substrate 100. The first lower insulation layer 102 may include, e.g., silicon oxide. An upper surface of the first lower insulation layer 102 may be substantially flat.

A plurality of first conductive layer patterns 106 may be disposed on the first lower insulation layer 102, and each of the plurality of first conductive layer patterns 106 may have a line shape extending in the first direction D1 that is parallel to the upper surface of the substrate 100. The first conductive layer patterns 106 may be arranged parallel to each other, and may be spaced apart from each other in the second direction D2 that is parallel to the upper surface of the substrate 100 and perpendicular to the first direction D1. Each of the first conductive layer pattern 106 may serve as a bit line.

A second lower insulation layer 108 may be disposed on the first lower insulation layer 102, and may at least partially fill a space between the first conductive layer patterns 106. Upper surfaces of the first conductive layer patterns 106 and the second lower insulation layer 108 may be coplanar with each other, and may be substantially flat. Accordingly, the upper surfaces of the first conductive layer patterns 106 may be exposed by the second lower insulation layer 108.

In one or more embodiments, the plurality of first conductive layer patterns 106 may include doped polysilicon, metal, conductive metal nitride, conductive metal silicide, conductive metal oxide, or a combination thereof. For example, the plurality of first conductive layer patterns 106 may include doped polysilicon, Al, Cu, Ti, Ta, Ru, W, Mo, Pt, Ni, Co, TiN, TaN, WN, WSi, NbN, TiAl, TiAlN, TiSi, TiSiN, TaSi, TaSiN, RuTiN, NiSi, CoSi, IrOx, RuOx, or a combination thereof, but embodiments are not limited thereto. The plurality of first conductive layer patterns 106 may include a single layer, or multiple layers of the above-described materials. For example, each of the first conductive layer patterns 106 may have a structure in which a titanium nitride layer, a tungsten layer, a tungsten silicide layer, and a titanium nitride layer are stacked.

A plurality of mold insulation structures 116 having line shapes extending in the second direction D2 may be disposed on the first conductive layer pattern 106 and the second lower insulation layer 108. The mold insulation structures 116 may be arranged to perpendicularly intersect the first conductive layer pattern 106. A first trench 118 extending in the second direction D2 may be formed between the mold insulation structures 116. A plurality of first trenches 118 may be provided.

Each of the mold insulation structures 116 may have a structure in which a first mold insulation pattern 112 and a second mold insulation pattern 114 are sequentially stacked in the vertical direction D3.

In one or more embodiments, the first mold insulation pattern 112 may include, e.g., silicon oxide. The second mold insulation pattern 114 may include, e.g., silicon nitride. A vertical thickness of the first mold insulation pattern 112 may be greater than a vertical thickness of the second mold insulation pattern 114.

The channel pattern 130a may be conformally formed on sidewalls of the mold insulation structures 116 facing each other and an upper surface of the first conductive layer pattern 106 between the mold insulation structures 116. The channel pattern 130a may be formed along profiles of the sidewalls of the mold insulation structures 116 facing each other and the upper surface of the first conductive layer pattern 106 between the mold insulation structures 116. Each of the mold insulation structures 116 may be disposed on outer walls of the channel patterns. The channel pattern 130a may include sidewall portions extending in the vertical direction D3 and a lower portion connecting two lower ends of the sidewall portions that face each other in the horizontal direction (i.e., first direction D1). Accordingly, the channel pattern 130a may have a U-shape in a cross-sectional view cut in the first direction D1.

Uppermost surfaces (i.e., both ends) of the channel pattern 130a may be lower than an upper surface of the mold insulation structure 116. The uppermost surface of the channel pattern 130a may be lower than an upper surface of the second mold insulation pattern 114.

Hereinafter, in a structure having U-shape, the inner space of the U-shape may be referred to as an inner portion. In addition, portions extending in the vertical direction D3 in the structures having U-shape may be referred to sidewall portions. A portion connecting lower ends of the sidewall portions in a horizontal direction may be referred to as a lower portion. Areas outside of the U-shape may be referred to outer portions or outer surfaces.

A lower surface of the channel pattern 130a may contact the upper surface of the first conductive layer pattern 106. A plurality of channel patterns 130a may be spaced apart from each other in the first direction D1 and the second direction D2. In one or more embodiments, the channel pattern 130a may not be formed on the second lower insulation layer 108. The mold insulation structure 116 may be disposed between the channel patterns 130a in the first direction D1.

The channel pattern 130a may include an oxide semiconductor material. In one or more embodiments, the channel pattern 130a may include InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. For example, the channel pattern 130a may include InxGayZnzO. In one or more embodiments, the channel pattern 130a may be amorphous.

The gate insulation layer 140 may be disposed along surfaces of an inner portion of the sidewalls of the channel pattern 130a and the lower portion of the channel pattern 130a. That is, the gate insulation layer 140 may be formed conformally along the inner portion of the U-shape of the channel pattern 130a. The gate insulation layer 140 may be formed on the inner surface of the channel pattern 130a. In addition, the gate insulation layer 140 may be formed on the mold insulation structure 116. In one or more embodiments, the gate insulation layer 140 may have a U-shape in the cross sectional view cut in the first direction D1. The gate insulation layer 140 may extend in the second direction D2.

The gate insulation layer 140 may include metal oxide having a dielectric constant that is greater than a dielectric constant of silicon nitride. In one or more embodiments, the gate insulation layer 140 may include aluminum oxide, zirconium oxide, hafnium oxide, or titanium oxide. For example, the gate insulation layer 140 may include aluminum oxide.

In one or more embodiments, an upper surface of the gate insulation layer 140 may be higher than the uppermost surface of the channel pattern 130a. Uppermost surfaces (e.g., both ends) of the gate insulation layer 140 on an inner portion of the sidewalls of the channel pattern 130a may be coplanar with the upper surface of the mold insulation structure 116. Accordingly, a third hole may be formed between the mold insulation structure 116 and the gate insulation layer 140 positioned higher than the uppermost surface of the channel pattern 130a.

The first gate electrode 150 may be disposed on an inner portion of the gate insulation layer 140 (e.g., the first gate electrode 150 may be formed on the sidewalls of the gate insulation layer 140). The first gate electrodes 150 may be disposed on the inside of the sidewall portions facing each other of the gate insulation layers 140 having the U-shape. The first gate electrode 150 may not be formed on a lower portion of gate insulation layer 140 having the U-shape. Each of the first gate electrodes 150 may extend in the second direction D2.

In one or more embodiments, an uppermost surface of the first gate electrode 150 may be coplanar with the uppermost surface of the channel pattern 130a. Accordingly, the first gate electrode 150 may face the sidewall portions of the channel pattern 130a and the sidewall portions of the gate insulation layer 140. In this case, the vertical channel transistor may have target electrical characteristics, and reliability defects of the gate insulation layer 140 may be decreased. However, depending on process variations or circuit design, the uppermost surface of the first gate electrode 150 may be slightly higher or lower than the uppermost surface of the channel pattern 130a. In this case, a height difference between the uppermost surface of the first gate electrode 150 and the uppermost surface of the channel pattern 130a may be less than about 5% of a vertical height of the channel pattern 130a. When the uppermost surface of the first gate electrode 150 is higher than the uppermost surface of the channel pattern 130a by more than 5% of the vertical height of the channel pattern 130a, an effect of reducing reliability defects of the gate insulation layer 140 may be decreased. When the uppermost surface of the first gate electrode 150 is lower than the uppermost surface of the channel pattern 130a by more than 5% of the vertical height of the channel pattern 130a, it may be difficult for the vertical channel transistor to have target electrical characteristics.

The first gate electrode 150 may include a conductive material having a first work function. The first gate electrode 150 may include a metal having a target work function for the vertical channel transistor having the target electrical characteristics (e.g., a threshold voltage characteristic).

The first gate electrode 150 may include, e.g., metal, conductive metal nitride, conductive metal silicide, conductive metal oxide, or a combination thereof. In one or more embodiments, the gate insulation layer 140 may include a metal oxide, and the first gate electrode 150 may include a metal material. For example, the first gate electrode 150 may include Ti, Ta, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but embodiments are not limited thereto.

The second gate electrode 170 may cover the surface (e.g., an exposed surface) of the first gate electrode 150. In addition, the second gate electrode 170 may cover a portion of the gate insulation layer 140 disposed on the uppermost surface of the first gate electrode 150. An uppermost surface of the second gate electrode 170 may be higher than the uppermost surface of the channel pattern 130a.

In one or more embodiments, the second gate electrode 170 may cover the sidewall portions and uppermost surface of the first gate electrode 150. A portion of the second gate electrode 170 disposed higher than the uppermost surface of the first gate electrode 150 may be referred to as an upper portion of the second gate electrode 170, and the upper portion of the second gate electrode 170 may contact a surface of the gate insulation layer 140.

In one or more embodiments, as shown in FIG. 4, the upper portion of the second gate electrode 170 may not include a vertical extension extending along the sidewall portion of the gate insulation layer 140 in the vertical direction D3.

In one or more embodiments, as shown in FIG. 5, the upper portion of the second gate electrode 170 may include a vertical extension extending along the sidewall of the gate insulation layer 140 in the vertical direction D3. In this case, the upper portion of the second gate electrode 170 may include a bent portion.

A stacked structure of the first gate electrode 150 and the second gate electrode 170 may serve as a gate electrode structure 172. The gate electrode structure 172 may serve as a gate electrode of a vertical channel transistor. The gate electrode structure 172 may extend in the second direction D2. The gate electrode structure 172 may serve as a word line of a semiconductor device.

A surface of a lower portion of the gate insulation layer 140 may be exposed between the gate electrode structures 172.

The uppermost surface of the second gate electrode 170 may be higher than the uppermost surface of the channel pattern 130a. Accordingly, the upper portion of the second gate electrode 170 may not face the sidewall portions of the channel pattern 130a. However, the upper portion of the second gate electrode 170 may face an upper portion of the sidewalls of the gate insulation layer 140.

The second gate electrode 170 may include a conductive material having a second work function that is greater than the first work function.

The second gate electrode 170 may include doped polysilicon, metal, conductive metal nitride, conductive metal silicide, conductive metal oxide, or a combination thereof. For example, the second gate electrode 170 may include doped polysilicon, Ti, Ta, W, Mo, Pt, Ni, Co, Ru, TiN, TaN, WN, NbN, TiAl, TiAlN, TiSi, TiSiN, TaSi, TaSiN, RuTiN, NiSi, CoSi, IrOx, RuOx, or a combination thereof. The material of the second gate electrode 170 may be selected as a material having a work function that is greater than the work function of the first gate electrode 150.

The capping insulation pattern 180 may be conformally formed on the surfaces of the gate insulation layer 140 and the second gate electrode 170. The buried insulation pattern 182 may be formed on the capping insulation pattern 180. The buried insulation pattern 182 may fill the inner portion of the gate insulation layer 140 having a U-shape. The buried insulation pattern 182 may have a line shape extending in the second direction D2. The buried insulation pattern 182 may face the mold insulation structure 116 in the first direction D1.

The capping insulation pattern 180 may include, e.g., silicon nitride. The buried insulation pattern 182 may include, e.g., silicon oxide.

An upper surface of the buried insulation pattern 182 may be coplanar with an uppermost surface of the gate insulation layer 140 on the upper surface of the mold insulation structure 116.

The first insulation layer 184 may be disposed on the capping insulation pattern 180, the buried insulation pattern 182, and the uppermost surface of the gate insulation layer 140. The first insulation layer 184 may include, e.g., silicon nitride.

The first contact plug 200 may pass through the first insulation layer 184, the capping insulation pattern 180, and the uppermost surface of the gate insulation layer 140, and may extend downward to contact the uppermost surface of the channel pattern 130a.

The first contact plug 200 may include an upper portion passing through the first insulation layer 184, the capping insulation pattern 180, and the uppermost surface of the gate insulation layer 140, and a lower portion disposed below the uppermost surface of the gate insulation layer 140. The upper portion of the first contact plug 200 may have a first width, and the lower portion of the first contact plug 200 may have a second width less than the first width. The lower portion of the first contact plug 200 may face a portion of the gate insulation layer 140 and a portion of the second gate electrode 170 in the horizontal direction (e.g., the first direction D1).

A bottom of the first contact plug 200 may directly contact the uppermost surface of the channel pattern 130a. A lower sidewall of the first contact plug 200 may contact upper portions of the mold insulation structure 116 and the gate insulation layer 140. In one or more embodiments, a portion of the first contact plug 200 may contact outer wall of the gate insulation layer 140.

In one or more embodiments, the first contact plug 200 may include a conductive material having a third work function equal to as or less than the first work function. In one or more embodiments, the first contact plug 200 may include doped polysilicon, metal, conductive metal nitride, conductive metal silicide, conductive metal oxide, or a combination thereof. For example, the first contact plug 200 may include doped polysilicon, Ti, Ta, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof. The first contact plug 200 may include a material selected as a material having a work function equal to or less than the work function of the first gate electrode 150.

In one or more embodiments, a height difference between the uppermost surface of the first gate electrode 150 and the uppermost surface of the channel pattern 130a may be less than a height difference between the uppermost surface of the second gate electrode 170 and the uppermost surface of the channel pattern 130a.

In one or more embodiments, the uppermost surface of the channel pattern 130a may be coplanar with the uppermost surface of the first gate electrode 150. In this case, the first contact plug 200 and the first gate electrode 150 may not face each other in a horizontal direction (e.g., a lateral direction D1). Accordingly, reliability defects of the gate insulation layer 140 due to overlap between the first contact plug 200 and the first gate electrode 150 having a low work function may be decreased.

Depending on process variations or circuit design, as shown in FIG. 40, when the uppermost surface of the channel pattern 130a is slightly higher than the uppermost surface of the first gate electrode 150, the first contact plug 200 and the first gate electrode 150 may not face each other in the first direction D1. The first contact plug 200 may face at least a portion of the second gate electrode 170 in the first direction D1. Accordingly, the first contact plug 200 may overlap the gate insulation layer 140 and the second gate electrode 170. Therefore, reliability defects of the gate insulation layer 140 may be decreased.

Depending on process variations or circuit design, as shown in FIG. 41, when the uppermost surface of the channel pattern 130a is slightly lower than the uppermost surface of the first gate electrode 150, on-currents of the vertical channel transistor may increase. In this case, the first contact plug 200 may face at least a portion of the first and second gate electrodes 150 and 170 in the first direction D1. A height of an area where the first contact plug 200 and the second gate electrode 170 face each other in the first direction D1 may be greater than a height of an area where the first contact plug 200 and the first gate electrode 150 face each other in the first direction D1. Accordingly, reliability defects of the gate insulation layer 140 may be decreased.

The first gate electrode 150 may face the channel pattern 130a and the gate insulation layer 140, such that the first gate electrode 150 may serve as a switching gate of the vertical channel transistor. The second gate electrode 170 may face the first contact plug 200 and the gate insulation layer 140, such that the second gate electrode 170 may not serve as a switching gate for the vertical channel transistor. A portion of the gate insulation layer 140 may be interposed between the first contact plug 200 and the second gate electrode 170.

As described above, the channel pattern 130a, the gate insulation layer 140, and the first gate electrode 150 may arranged in the first direction D1, such that the channel pattern 130a, the gate insulation layer 140, and the first gate electrode 150 may be operated as the vertical channel transistor. The first gate electrode 150 may have the first work function, such that the vertical channel transistor may have the target electrical characteristics. In addition, the first contact plug 200 contacting the uppermost surface of the channel pattern 130a may overlap the gate insulation layer 140 and the second gate electrode 170, and the second gate electrode 170 may have the work function that is greater than the work function of the first gate electrode 150. Accordingly, off-currents generated in an area where the first contact plug 200, the gate insulation layer 140, and the second gate electrode 170 overlap may be decreased. Additionally, reliability defects of the gate insulation layer 140 occurred in the area where the first contact plug 200, the gate insulation layer 140, and the second gate electrode 170 overlap may be decreased.

Examples of a metal used as each of the first gate electrode 150, the second gate electrode 170, and the first contact plug 200 may be presented in a following table.

TABLE 1

| | first gate | second gate | first |
|---|---|---|---|
| | electrode | electrode | contact plug |
| Example 1 | TiN | Ti | TiN |
| Example 2 | Ti | TiN | Ti |
| Example 3 | Ta | TiN | Ta |
| Example 4 | Ti | Ni | Ti |
| Example 5 | Ta | Ni | Ta |
| Example 6 | TiN | Ru | TiN |
| Example 7 | Ti | Ru | Ti |
| Example 8 | Ta | Ru | Ta |

The second conductive layer pattern 202 may be disposed on the first insulation layer 184, and may contact the upper surface of the first contact plug 200. In one or more embodiments, the second conductive layer pattern 202 and the first contact plug 200 may include the same material. In one or more embodiments, the second conductive layer pattern 202 and the first contact plug 200 may be one body, such that an interface between the second conductive layer pattern 202 and the first contact plug 200 may not be formed. The second conductive layer pattern 202 may serve as a landing pad for connecting the capacitor 226.

The second contact plug 204 may directly contact an edge portion of the gate electrode structure 172 in the second direction D2. An electrical signal may be applied to the gate electrode structure 172 through the second contact plug 204.

The second contact plug 204 may pass through the first insulation layer 184, the capping insulation pattern 180 and the buried insulation pattern 182, and may extend downward to the surface of the lower portion of the gate insulation layer 140. In one or more embodiments, the second contact plug 204 may contact the uppermost surface and a sidewall of the second gate electrode 170.

The third conductive layer pattern 206 may be disposed on the first insulation layer 184, and may contact an upper surface of the second contact plug 204. In one or more embodiments, the third conductive layer pattern 206 and the second contact plug 204 may include the same material. In one or more embodiments, the third conductive layer pattern 206 and the second contact plug 204 may be one body, such that an interface between the third conductive layer pattern 206 and the second contact plug 204 may not be formed.

In one or more embodiments, the second conductive layer pattern 202, the third conductive layer pattern 206, the first contact plug 200, and the second contact plug 204 may include the same material.

The second insulation pattern 208 may be formed on the first insulation layer 184, and may fill a space between the second conductive layer patterns 202 and a space of the third conductive layer patterns 206. An upper surface of the second insulation pattern 208 and upper surfaces of the second and third conductive layer patterns 202 and 206 may be coplanar with each other. The upper surfaces of the second insulation pattern 208 and the second and third conductive layer patterns 202 and 206 may be substantially flat. The second insulation pattern 208 may include, e.g., silicon oxide.

The first etch stop layer 210 may be disposed on the second insulation pattern 208 and the second conductive layer pattern 202. The first etch stop layer 210 may include, e.g., silicon nitride.

The capacitor 226 may pass through the first etch stop layer 210, and may be disposed on the upper surface of the second conductive layer pattern 202. The capacitor 226 may include a lower electrode 220, a dielectric layer 222, and an upper electrode 224 sequentially stacked. The lower electrode 220 may directly contact the upper surface of the third conductive layer pattern 206. The lower electrode 220 may have a pillar shape or a cylinder shape.

The lower electrode 220 of the capacitor 226 may be electrically connected to the channel pattern 130a through the second conductive layer pattern 202 and the first contact plug 200.

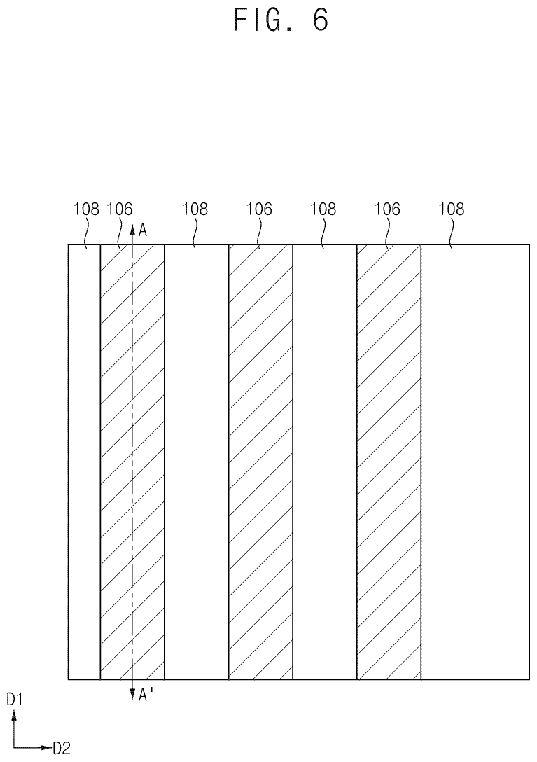

FIGS. 6 to 38 are diagrams illustrating a method of manufacturing a semiconductor device according to one or more embodiments.

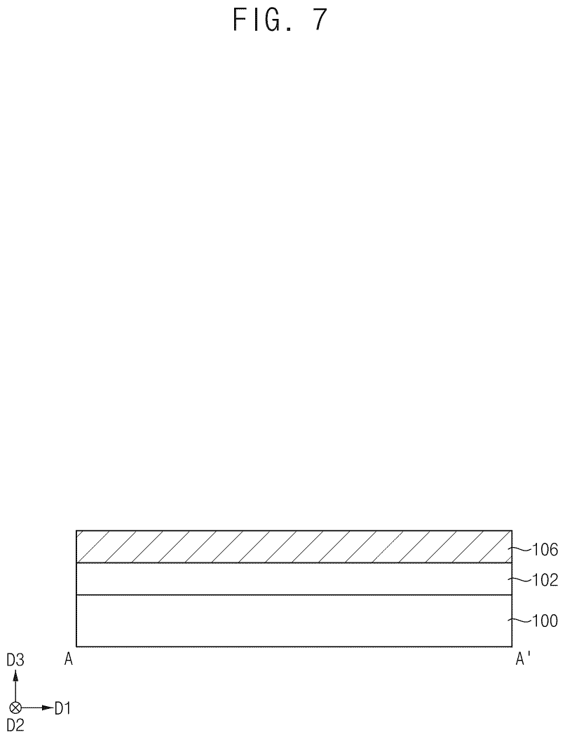

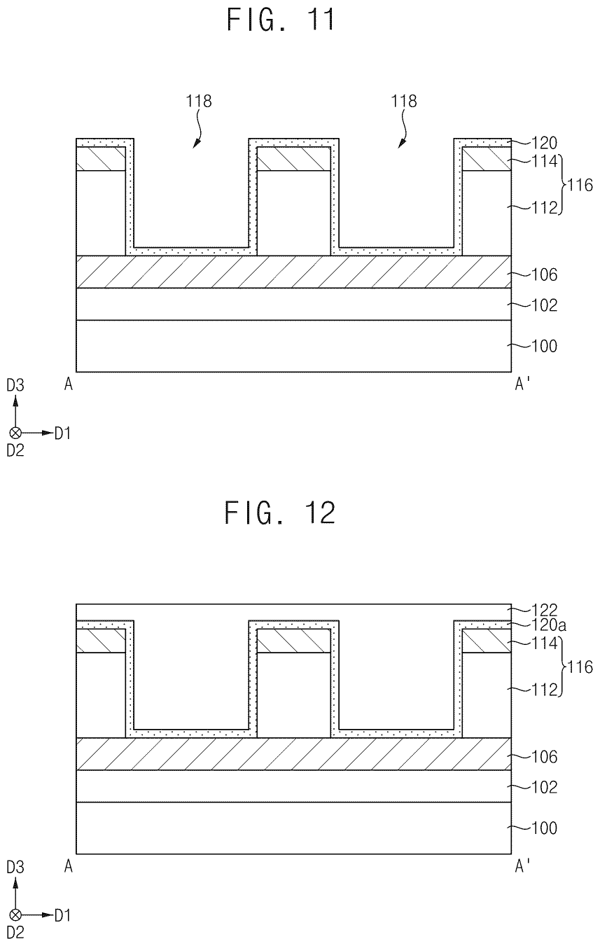

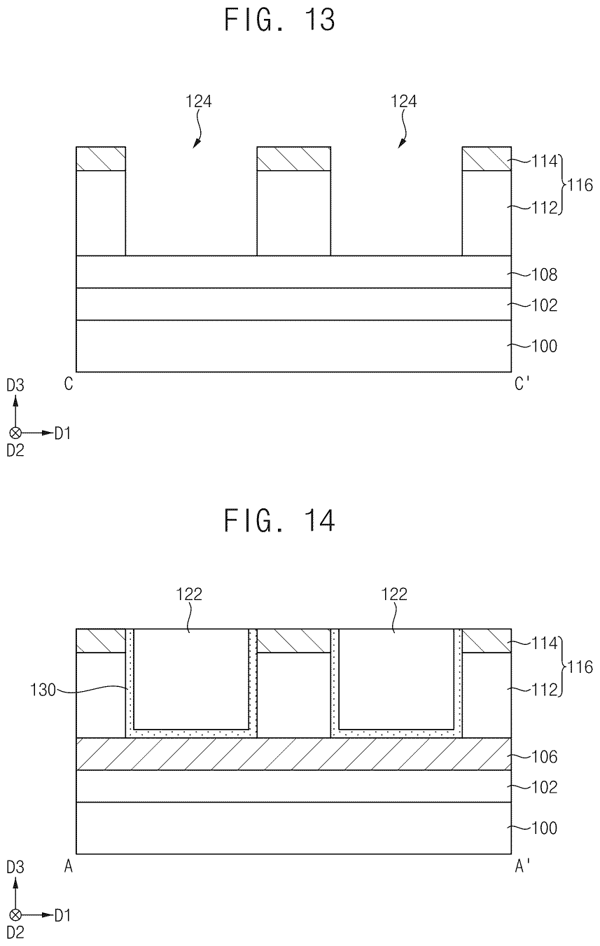

FIGS. 6, 8, 10, 16, 19, 24, 32 and 37 are plan views. FIGS. 7, 9, 11, 12, 14, 17, 18, 20 to 23, 25 to 29, 31, 33, 34, 35 and 38 are cross-sectional views taken along line A-A′. FIGS. 30 and 36 are cross-sectional views cut along line B-B′. FIGS. 13 and 15 are cross-sectional views taken along line C-C′.

Referring to FIGS. 6 and 7, a first lower insulation layer 102 may be formed on a substrate 100.

First conductive layer patterns 106 having a line shape extending in the first direction D1 may be formed on the first lower insulation layer 102. The first conductive layer patterns 106 may be parallel to each other, and may be spaced apart from each other in the second direction D2. A second lower insulation layer 108 may be formed on the first lower insulation layer 102 between the first conductive layer patterns 106. Upper surfaces of the first conductive layer patterns 106 and the second lower insulation layer 108 may be coplanar with each other, and may be substantially flat.

In one or more embodiments, the first and second lower insulation layers 102 and 108 may include silicon oxide. In one or more embodiments, the first conductive layer pattern 106 may include metal.

In one or more embodiments, the first conductive layer patterns 106 may be formed by an embossed manner. In this case, a first conductive layer may be formed on the first lower insulation layer 102. The first conductive layer may be patterned by a photolithography process to form the first conductive layer patterns 106. Thereafter, an insulation layer may be formed on the first conductive layer patterns 106. The insulation layer may be planarized until upper surfaces of the first conductive layer patterns 106 are exposed to form the second lower insulation layer 108.

In one or more embodiments, the first conductive layer patterns 106 may be formed by damascene process. In this case, a second lower insulation layer 108 may be formed on the first lower insulation layer 102. The second lower insulation layer may be patterned by a photolithography process to form trenches. A first conductive layer may be formed on the second lower insulation layer 108 to fill the trenches. The first conductive layer may be planarized until an upper surface of the second lower insulation layer 108 is exposed to form the first conductive layer patterns 106. The first conductive layer patterns 106 may be formed in the trenches, respectively.

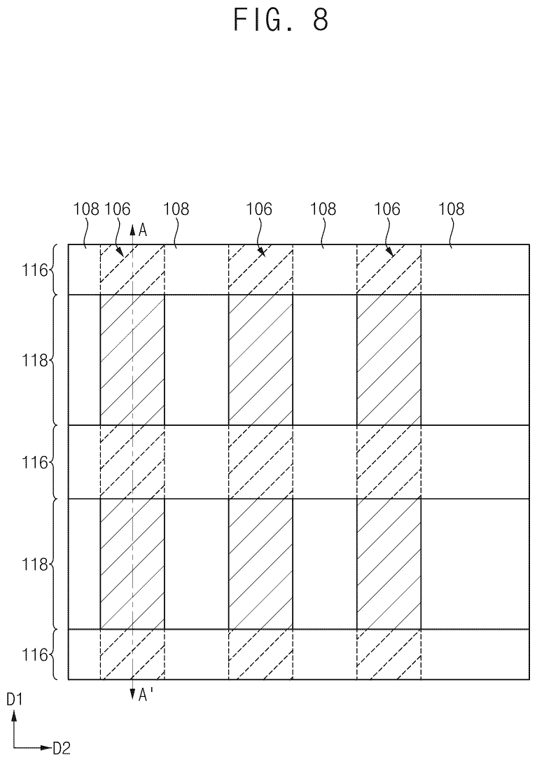

Referring to FIGS. 8 and 9, a first mold insulation layer and a second mold insulation layer may be sequentially formed on the first conductive layer pattern 106 and the second lower insulation layer 108. The first and second mold insulation layers may be patterned to form mold insulation structures 116. Each of the mold insulation structures 116 may have a structure in which a first mold insulation pattern 112 and a second mold insulation pattern 114 are stacked. A thickness of the second mold insulation pattern 114 may be greater than a thickness of the first mold insulation pattern 112.

In one or more embodiments, the first mold insulation pattern 112 may include, e.g., silicon oxide. The second mold insulation pattern 114 may include, e.g., silicon nitride.

The mold insulation structures 116 may have a line shape extending in the second direction D2. The mold insulation structures 116 may be spaced apart from each other in the first direction D1. A first trench 118 extending in the second direction D2 may be formed between the mold insulation structures 116. The first conductive layer pattern 106 and the second lower insulation layer 108 may be exposed by a bottom of the first trench 118.

The mold insulation structures 116 may serve as a mold for forming a channel pattern, a gate insulation layer pattern, and a gate electrode structure in subsequent processes.

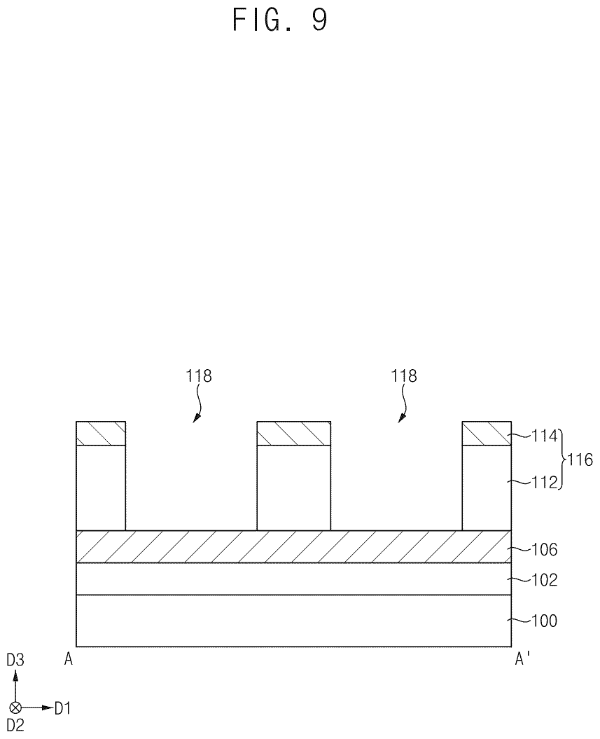

Referring to FIGS. 10 and 11, a channel layer 120 may be conformally formed along a surface of the mold insulation structure 116 and the bottom of the first trench 118. The channel layer 120 may include an oxide semiconductor layer. The oxide semiconductor layer may serve as a channel pattern for a vertical channel transistor by subsequent processes.

The channel layer 120 may cover the surface of the mold insulation structure 116, the upper surface of the first conductive layer pattern 106, and the upper surface of the second lower insulation layer 108. The channel layer 120 may be formed to have a uniform thickness along the surface profile of the first trench 118. The channel layer 120 may not completely fill the first trench 118. The channel layer 120 may contact the first conductive layer pattern 106.

In one or more embodiments, the channel layer 120 may be amorphous. In one or more embodiments, the channel layer 120 may include InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. For example, the channel layer 120 may include InxGayZnzO.

In one or more embodiments, the channel layer 120 may be formed by an atomic layer deposition process.

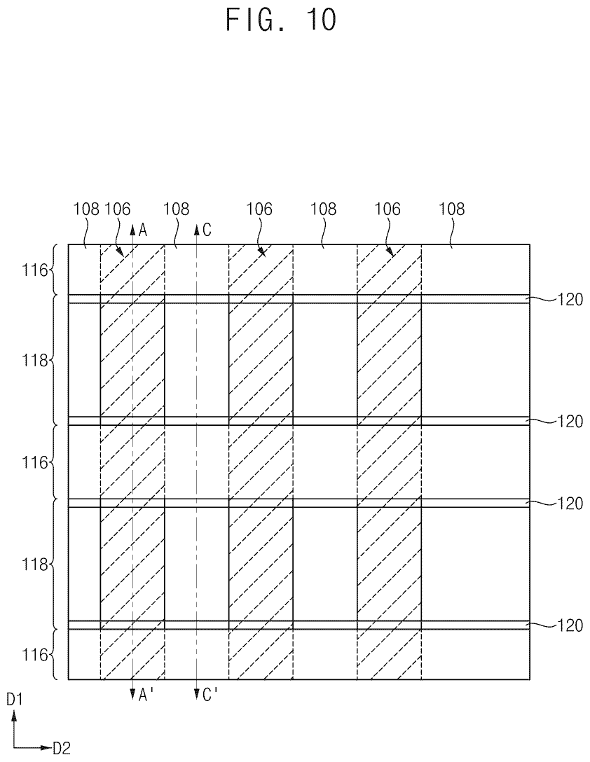

Referring to FIGS. 12 and 13, a first sacrificial layer may be formed on the channel layer 120. The first sacrificial layer may fill the first trench 118. An upper surface of the first sacrificial layer may be substantially flat. In one or more embodiments, the first sacrificial layer may include a spin-on hard mask. The spin-on hard mask may include amorphous carbon.

A first etch mask may be formed on the first sacrificial layer, and the first sacrificial layer may be anisotropically etched using this mask to form the first sacrificial layer pattern 122. Subsequently, the channel layer 120 may be anisotropically etched using the first sacrificial layer pattern 122 as an etch mask to form a first preliminary channel pattern 120a. Accordingly, the first preliminary channel patterns 120a may be spaced apart from each other in the second direction D2.

In one or more embodiments, the first etch mask may be a photoresist pattern. The first etch mask may overlap the upper surface of the first conductive layer pattern 106. Accordingly, the first sacrificial layer pattern 122 may cover the upper surface of the first conductive layer pattern 106, and may extend in the first direction D1. A first opening 124 may be formed between the first sacrificial layer patterns 122 and the mold insulation structures 116. The second lower insulation layer 108 may be exposed by a bottom of the first opening 124. A lower surface of the first preliminary channel pattern 120a may contact the first conductive layer pattern 106.

Referring to FIGS. 14 and 15, a second sacrificial layer 126 may be formed on the second lower insulation layer 108, the mold insulation structure 116, the first sacrificial layer pattern 122, and the first preliminary channel pattern 120a. The second sacrificial layer 126 may fill the first opening 124. An upper surface of the second sacrificial layer 126 may be higher than an uppermost surface of the first preliminary channel pattern 120a.

In one or more embodiments, the second sacrificial layer 126 may include a material the same as a material of the first sacrificial layer pattern 122. Accordingly, the second sacrificial layer 126 and the first sacrificial layer pattern 122 may be merged into one sacrificial layer pattern.

In one or more embodiments, the second sacrificial layer 126 may include a spin-on hard mask.

Upper portions of the second sacrificial layer 126, the first sacrificial layer pattern 122, and the first preliminary channel pattern 120a may be removed to expose an upper surface of the mold insulation structure 116. Accordingly, the first preliminary channel pattern 120a may be separated into a plurality of second preliminary channel patterns 130. The planarization process may include an etch-back process.

Each of the second preliminary channel patterns 130 may be formed along profiles of sidewalls of the mold insulation structures 116 and the upper surface of the first conductive layer pattern 106 between the mold insulation structures 116. Each of the second preliminary channel patterns 130 may have a U-shape, in a cross-sectional view. The second preliminary channel patterns 130 may be spaced apart from each other in the first direction D1 and the second direction D2. The second preliminary channel patterns 130 may be repeatedly arranged. A lower surface of each of the second preliminary channel patterns 130 may contact the first conductive layer pattern 106.

The mold insulation structure 116 may be disposed between the second preliminary channel patterns 130 in the first direction D1. The mold insulation structure 116 may be arranged in the first direction D1. The second lower insulation layer 108 may be exposed between the second preliminary channel patterns 130 in the second direction D2.

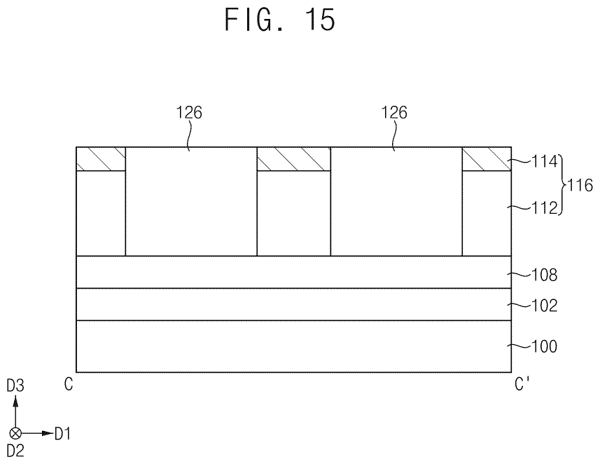

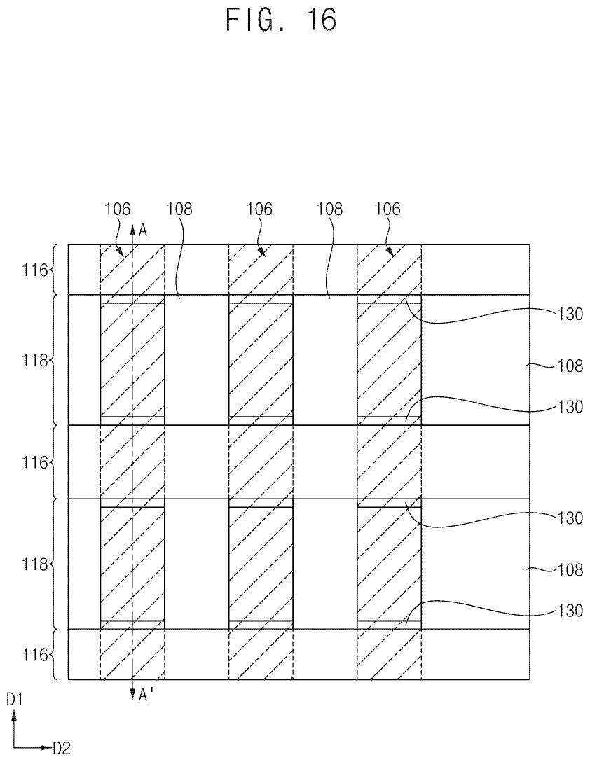

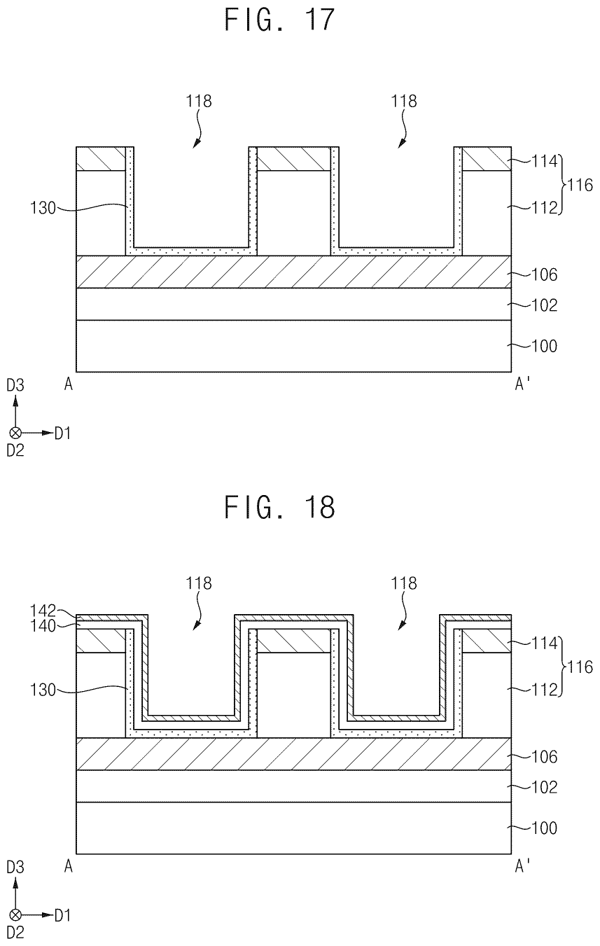

Referring to FIGS. 16 and 17, the first sacrificial layer pattern 122 and the second sacrificial layer 126 may be removed. The removing process of the first sacrificial layer pattern 122 and the second sacrificial layer 126 may include an ashing process and a cleaning process. Accordingly, an upper surface of the second preliminary channel pattern 130 may be exposed.

The first trench 118 may be formed again between the mold insulation structures 116.

Referring to FIG. 18, a gate insulation layer 140 may be formed on the second preliminary channel pattern 130, the mold insulation structure 116, and the second lower insulation layer 108. A first gate electrode layer 142 may be formed on the gate insulation layer 140. The gate insulation layer 140 and the first gate electrode layer 142 may be formed conformally on the second preliminary channel pattern 130, the mold insulation structure 116, and the second lower insulation layer 108. The gate insulation layer 140 and the first gate electrode layer 142 may be formed along surface profiles of the second preliminary channel pattern 130, the mold insulation structure 116, and the second lower insulation layer 108.

The gate insulation layer 140 may include metal oxide having a dielectric constant higher than a dielectric constant of silicon nitride. For example, the gate insulation layer 140 may include aluminum oxide.

The first gate electrode layer 142 may include a metal having a first work function. The first gate electrode layer 142 may include a material having a target work function for the vertical channel transistor having target electrical characteristics (e.g., threshold voltage characteristics).

In one or more embodiments, the gate insulation layer 140 and the first gate electrode layer 142 may be formed by an atomic layer deposition process.

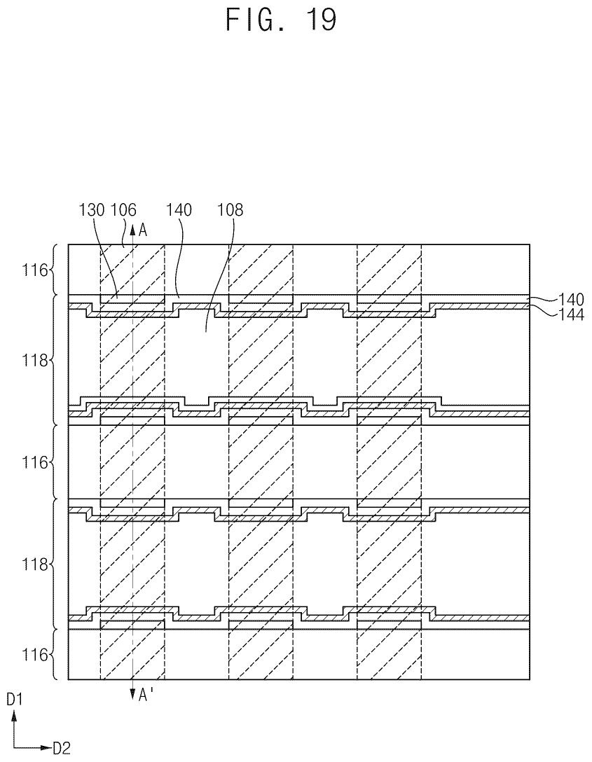

Referring to FIGS. 19 and 20, the first gate electrode layer 142 may be anisotropically etched, such that the first gate electrode layer 142 on the mold insulation structures and the first gate electrode layer 142 between the mold insulation structures may be removed. Accordingly, the first gate electrode layers 142 may be separated from each other to form a first preliminary gate electrode 144. The first preliminary gate electrode 144 may be formed on the gate insulation layer 140 on the sidewall of the mold insulation structure 116. The first preliminary gate electrode 144 may extend in the second direction D2.

Referring to FIG. 21, a third sacrificial layer may be formed to cover the first preliminary gate electrode 144 and the gate insulation layer 140. An upper surface of the third sacrificial layer may be higher than an uppermost surface of the gate insulation layer 140. The upper surface of the third sacrificial layer may be substantially flat. In one or more embodiments, the third sacrificial layer may include a spin-on hard mask.

The third sacrificial layer may be etched back to form a third sacrificial layer pattern 146. An upper surface and upper sidewalls of the first preliminary gate electrode 144 may be exposed by the third sacrificial layer pattern 146. The upper surface of the third sacrificial layer pattern 146 may be coplanar with a target uppermost surface of a first gate electrode subsequently formed. The target upper surface of the first gate electrode may be lower than an uppermost surface of the second preliminary channel pattern 130.

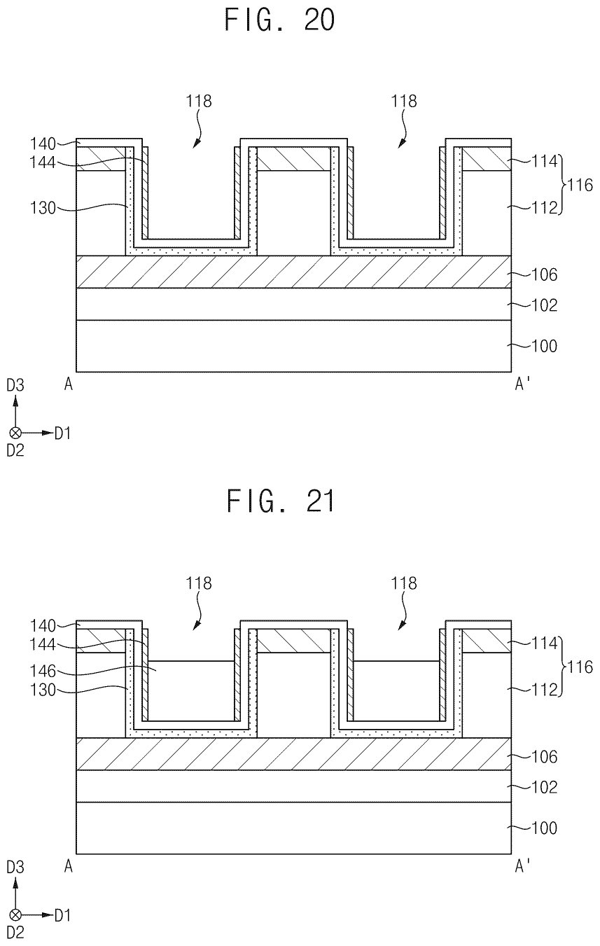

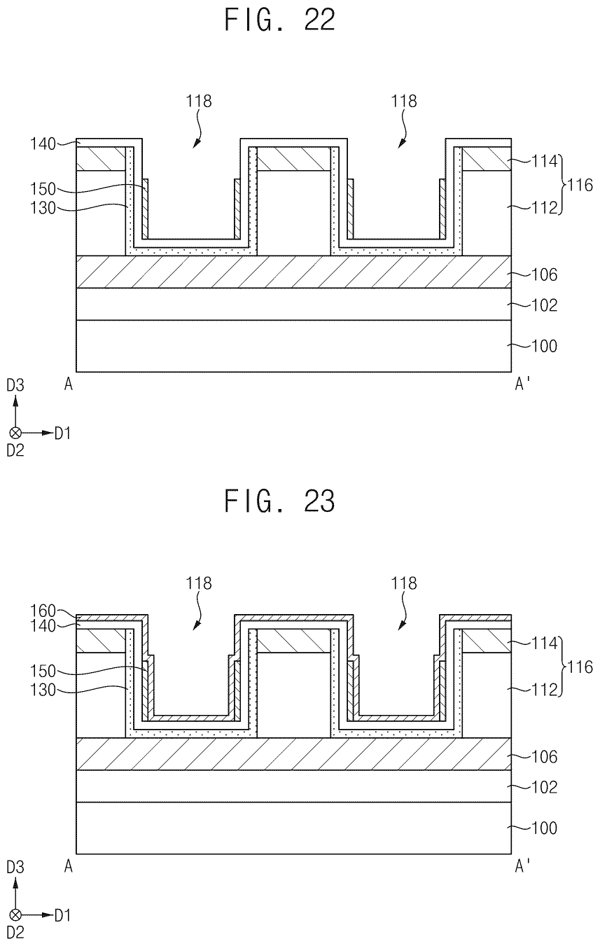

Referring to FIG. 22, the first preliminary gate electrode 144 exposed by the third sacrificial layer pattern 146 may be etched to form a first gate electrode 150. The etching process may include a wet etching process.

An uppermost surface of the first gate electrode 150 may be lower than an uppermost surface of the first preliminary gate electrode 144. By the above process, the first gate electrode 150 may have the target uppermost surface.

In one or more embodiments, the uppermost surface of the first gate electrode 150 may be coplanar with a bottom of a first contact plug subsequently formed. In one or more embodiments, depending on process distribution, the uppermost surface of the first gate electrode 150 may be slightly lower than the bottom of the first contact plug.

The third sacrificial layer pattern 146 is removed by an ashing process and a stripping process.

Referring to FIG. 23, a second gate electrode layer 160 may be conformally formed on the gate insulation layer 140 and the first gate electrode 150. The second gate electrode layer 160 may be formed along the surface profiles of the gate insulation layer 140 and the first gate electrode 150.

The second gate electrode layer 160 may include a metal or polysilicon having a work function that is greater than the work function of the first gate electrode 150. The second gate electrode layer 160 may be provided to decrease reliability defects of the gate insulation layer 140.

In one or more embodiments, the second gate electrode layer 160 may be formed by an atomic layer deposition process.

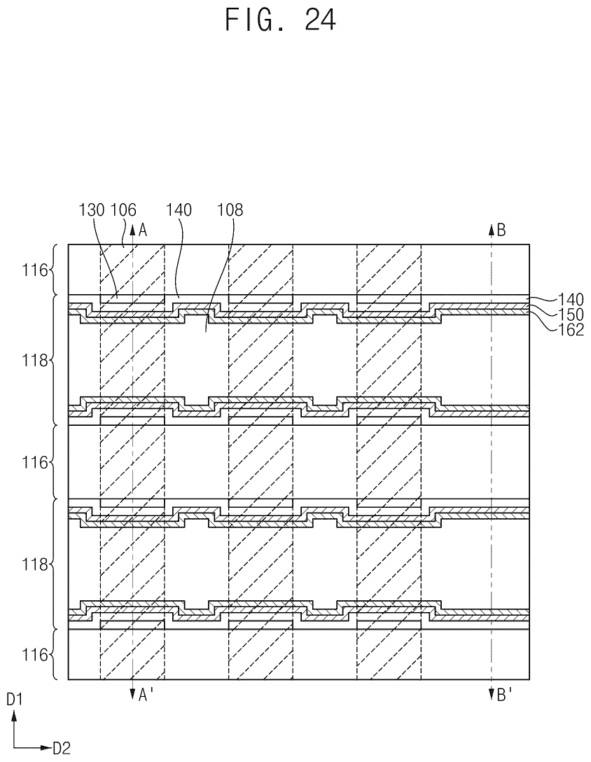

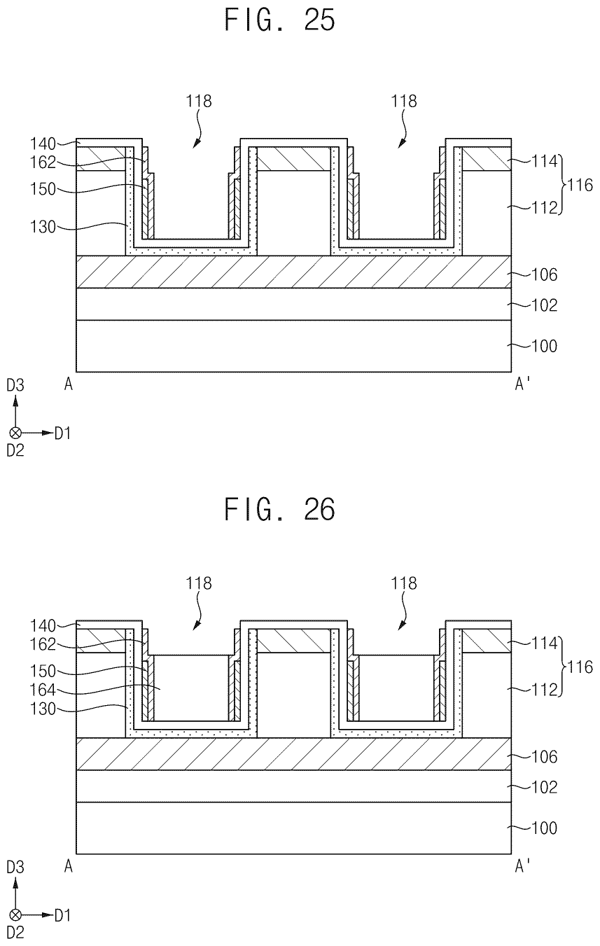

Referring to FIGS. 24 and 25, the second gate electrode layer 160 may be anisotropically etched, such that the second gate electrode layer 160 formed on the upper surfaces of the mold insulation structures 116 and between the mold insulation structures 116 may be removed. Accordingly, the second gate electrode layers 160 may be separated from each other to form a second preliminary gate electrode 162. The second preliminary gate electrode 162 may cover the upper surface and the sidewall of the first gate electrode 150. The second preliminary gate electrode 162 may extend in the second direction D2.

Referring to FIG. 26, a fourth sacrificial layer may be formed to cover the second preliminary gate electrode 162 and the gate insulation layer 140. An upper surface of the fourth sacrificial layer may be higher than the uppermost surface of the gate insulation layer 140. The upper surface of the fourth sacrificial layer may be substantially flat. In one or more embodiments, the fourth sacrificial layer may include a spin-on hard mask.

The fourth sacrificial layer may be etched back until an upper surface and an upper sidewall of the second preliminary gate electrode 162 are exposed to form a fourth sacrificial layer pattern 164. An upper surface of the fourth sacrificial layer pattern 164 may be substantially coplanar with a target upper surface of a second gate electrode subsequently formed.

The second gate electrode may cover an entire exposed surface of the first gate electrode 150. Additionally, an uppermost surface of the second gate electrode may be lower than the uppermost surface of the second preliminary channel pattern 130. Accordingly, an uppermost surface of the fourth sacrificial layer pattern 164 may be higher than an uppermost surface of the first gate electrode 150. Therefore, the upper surface of the fourth sacrificial layer pattern 164 may be lower than the uppermost surface of the second preliminary channel pattern 130.

The second preliminary gate electrode 162 may be bent on the uppermost surface of the first gate electrode 150, and may be formed along the surface profile of the gate insulation layer 140 exposed by the first gate electrode 150.

In one or more embodiments, the upper surface of the fourth sacrificial layer pattern 164 may be substantially coplanar with the bent portion of the second preliminary gate electrode 162, or may be higher than the bent portion of the second preliminary gate electrode 162.

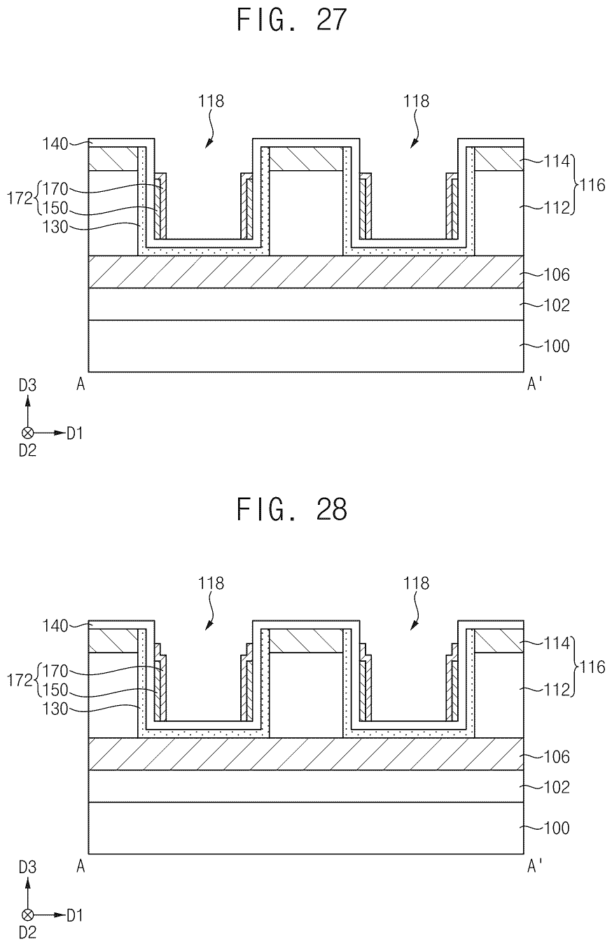

Referring to FIGS. 27 and 28, the second preliminary gate electrode 162 exposed by the fourth sacrificial layer pattern 164 may be etched to form the second gate electrode 170. The etching process may include a wet etching process.

The fourth sacrificial layer pattern 164 may be removed by an ashing process and a stripping process.

The first and second gate electrodes 150 and 170 may serve as a gate electrode structure 172. The gate electrode structure 172 may be used as a word line in a semiconductor device.

Depending on positions of the fourth sacrificial layer pattern, a shape of the second gate electrode 170 may be changed.

In one or more embodiments, the second preliminary gate electrode 162 disposed above the bent portion may be removed in the removing process, such that the second gate electrode 170 as shown in FIG. 27 may be formed. The second gate electrode 170 on the surface of the gate insulation layer 140 above the uppermost surface of the first gate electrode 150 may not extend in the vertical direction D3. The following processes may be described using the second gate electrode 170 shown in FIG. 27 as an example.

In one or more embodiments, the second preliminary gate electrode 162 disposed above the bent portion may partially remain, after the removing process. Therefore, as shown in FIG. 28, the second gate electrode 170 may be bent on the uppermost surface of the first gate electrode 150. The second gate electrode 170 on the surface of the gate insulation layer 140 above the uppermost surface of the first gate electrode 150 may extend in the vertical direction D3, such that the second gate electrode 170 may include a portion extending in the vertical direction D3.

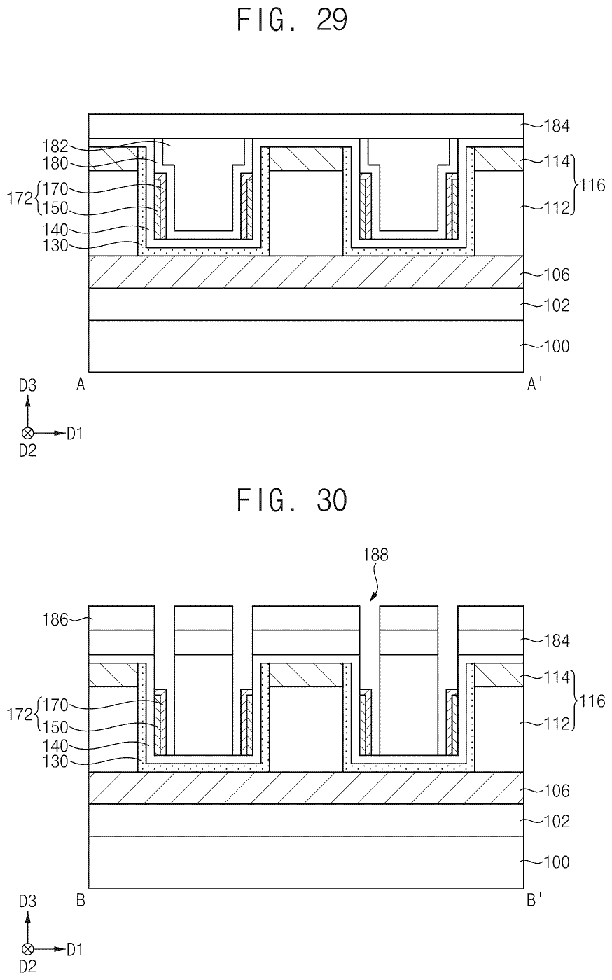

Referring to FIG. 29, a capping insulation layer may be conformally formed on the second gate electrode 170, the gate insulation layer 140, and the mold insulation structure 116. A buried insulation layer is formed on the capping insulation layer to completely fill the first trench 118.

The capping insulation layer may include, e.g., silicon nitride. The buried insulation layer may include, e.g., silicon oxide.

Thereafter, the buried insulation layer and the capping insulation layer may be planarized until the uppermost surface of the gate insulation layer 140 is exposed to form a capping insulation pattern 180 and a buried insulation pattern 182. The capping insulation pattern 180 and the buried insulation pattern 182 may be formed on the surface of the gate insulation layer 140 and the second gate electrode 170 in the first trench 118. The capping insulation pattern 180 and the buried insulation pattern 182 may fill the first trench 118.

In one or more embodiments, the planarization process may include a chemical mechanical polishing (CMP) process and/or an etch back process.

Thereafter, a first insulation layer 184 may be formed on the gate insulation layer 140, the capping insulation pattern 180, and the buried insulation pattern 182. In an example embodiment, the first insulation layer 184 may include silicon nitride.

Referring to FIG. 30, a second etch mask 186 may be formed on the first insulation layer 184. The second etch mask 186 may be a photoresist pattern. The second etch mask 186 may include a hole exposing an edge portion of the gate electrode structure 172 in the second direction D2. The hole may overlap at least an upper surface and a sidewall of the edge portion of the gate electrode structure 172 in the second direction D2.

The first insulation layer 184, the capping insulation pattern 180, and the buried insulation pattern 182 may be etched using the second etch mask 186 to form a first hole 188. An upper surface and a sidewall of an edge in the second direction D2 of the second gate electrode 170 may be exposed by the first hole 188.

Thereafter, the second etch mask 186 may be removed.

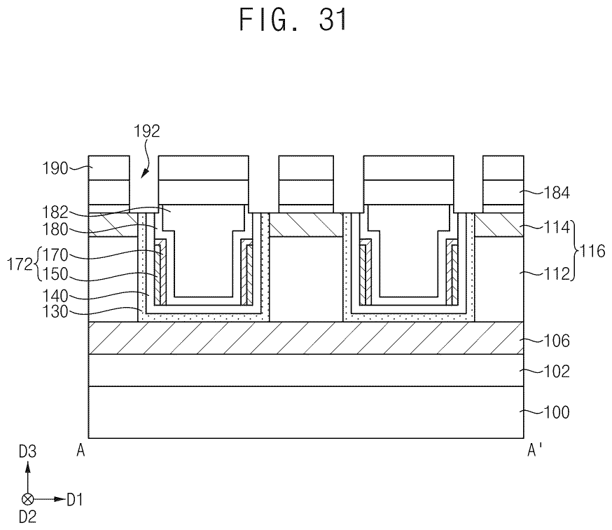

Referring to FIG. 31, a third etch mask 190 may be formed on the first insulation layer 184. The third etch mask 190 may be a photoresist pattern.

The third etch mask 190 may include holes facing the uppermost surfaces (i.e., both ends) of the second preliminary channel pattern 130. Each of the holes included in the third etch mask 190 may face the uppermost surface of the second preliminary channel pattern 130 and a portion of the mold insulation structure 116 adjacent the second preliminary channel pattern 130. Additionally, the third etch mask 190 may cover all or most of an area facing the upper surface of the buried insulation pattern 182.

The first insulation layer 184, the gate insulation layer 140, and the capping insulation pattern 180 may be etched using the third etch mask 190 to form a second hole 192. The second preliminary channel pattern 130, the gate insulation layer 140, and the capping insulation pattern 180 may be exposed by a bottom of the second hole 192.

The etching process of the first insulation layer 184 may include, e.g., a dry etching process. The etching process of the gate insulation layer 140 may include, e.g., a wet etching process.

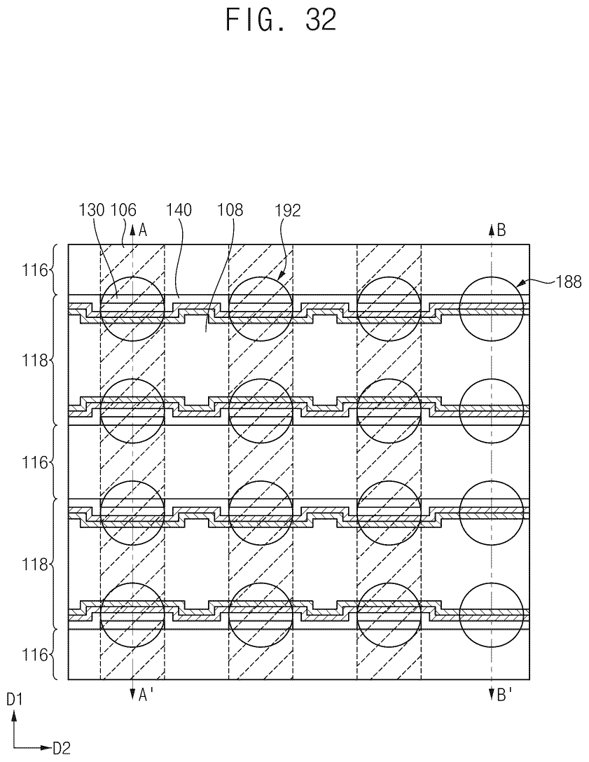

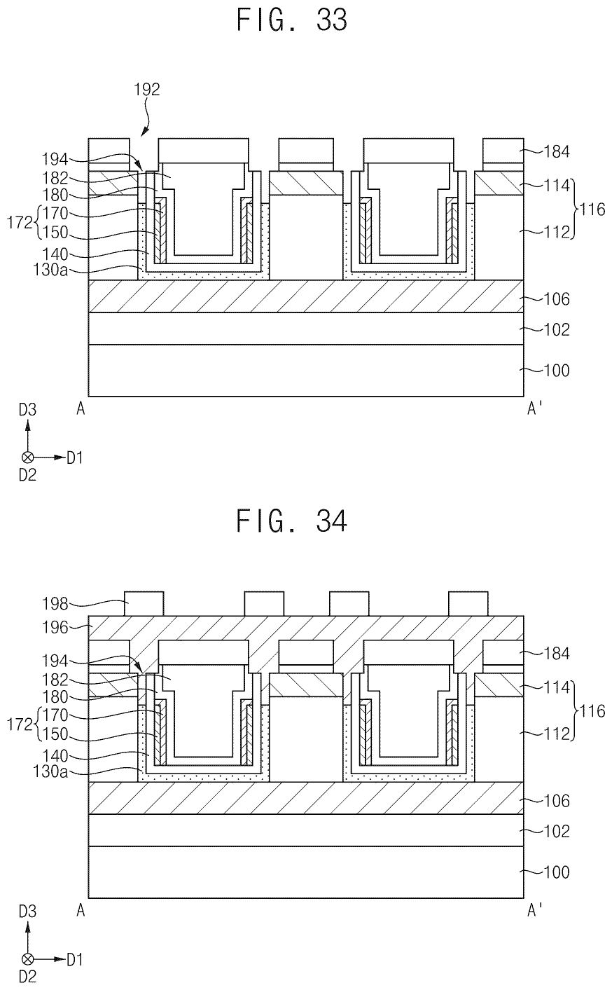

Referring to FIGS. 32 and 33, the second preliminary channel pattern 130 exposed by the bottom of the second hole 192 may be selectively etched to form a third hole 194. The third hole 194 may communicate with the second hole 192, and may have an inner width less than an inner width of the second hole 192. As the third hole 194 is formed, a height of the uppermost surface of the second preliminary channel pattern 130 may be decreased to form a channel pattern 130a.

An uppermost surface of the channel pattern 130a may be exposed by the bottom of the third hole 194. At least the upper sidewall of the gate insulation layer 140 and the sidewall of the second mold insulation pattern 114 may be exposed by a sidewall of the third hole 194. In one or more embodiments, the upper sidewall of the first mold insulation pattern 112 may be exposed by the sidewall of the third hole 194.

The bottom of the third hole 194 may be coplanar with the uppermost surface of the first gate electrode 150. In one or more embodiments, depending on process variations, the bottom of the third hole 194 may be slightly higher than the uppermost surface of the first gate electrode 150. Accordingly, the sidewall of the third hole 194 may not face the first gate electrode 150. The sidewall of the third hole 194 may face the second gate electrode 170.

Thereafter, the third etch mask 190 may be removed.

Referring to FIG. 34, a second conductive layer 196 may be formed on the first insulation layer 184 to fill the first hole 188, second hole 192, and third hole 194.

The second conductive layer 196 may include a metal. The second conductive layer 196 may include a metal having a work function equal to or less than the first work function.

A fourth etch mask 198 may be formed on the second conductive layer 196. The fourth etch mask 198 may include, e.g., a photoresist pattern.

The fourth etch mask 198 may have an isolated shape covering an area facing each of the first and second holes 188 and 192.

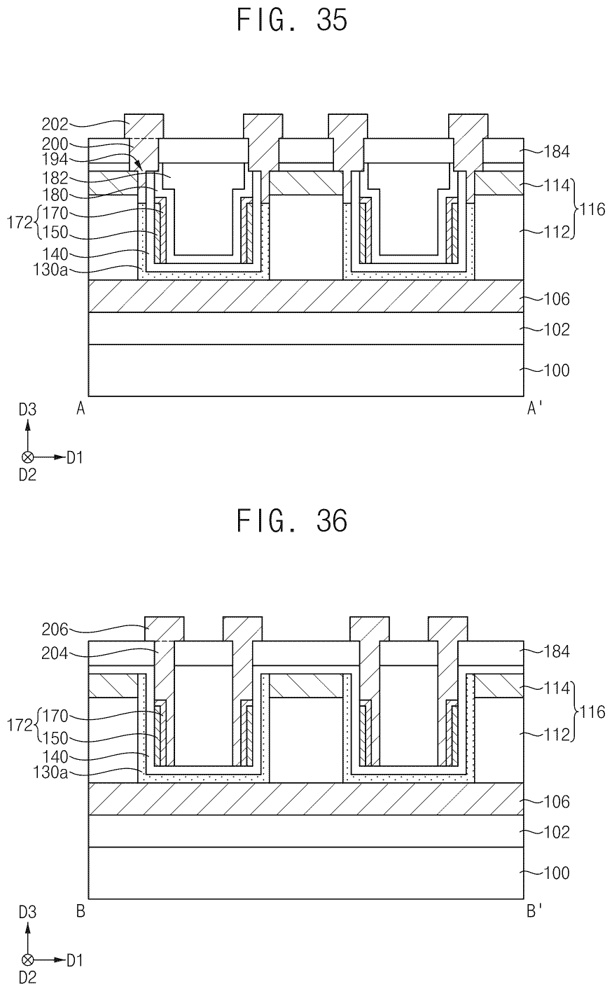

Referring to FIGS. 35 and 36, the second conductive layer 196 may be etched using the fourth etch mask 198 to form a first contact plug 200. The first contact plug 200 may be formed in the second hole 192 and the third hole 194. In addition, a second conductive layer pattern 202 may be formed on the first contact plug 200. A second contact plug 204 may be formed in the first hole 188. In addition, a third conductive layer pattern 206 may be formed on the second contact plug 204.

The first contact plug 200 may directly contact the uppermost surface of the channel pattern 130a. Accordingly, an electrical signal may be input and output to the channel pattern 130a through the first contact plug 200. The second conductive layer pattern 202 may serve as a landing pad for connecting a capacitor.

The first contact plug 200 may include an upper portion having a first width and a lower portion having a width less than the first width. The upper portion of the first contact plug 200 may correspond to an inner portion of the second hole 192, and the lower portion of the first contact plug 200 may correspond to an inner portion of the third hole 194.

A sidewall of the first contact plug 200 may face a portion of the gate insulation layer 140 and a portion of the second gate electrode 170. That is, the portion of the gate insulation layer 140 may be interposed between the first contact plug 200 and the second gate electrode 170.

The second contact plug 204 may directly contact the gate electrode structure 172. Accordingly, electrical signals may be applied to the gate electrode structure 172 through the second contact plug 204.

For operating the vertical channel transistor, a voltage may be repeatedly supplied to the first contact plug 200 and the gate electrode structure 172. Therefore, the gate insulation layer 140 disposed between the first contact plug 200 and the gate electrode structure 172 may be breakdown and/or damaged by the repeated voltage supplying. That is, reliability defects of the gate insulation layer 140 may occur. For example, a Time-Dependent Dielectric Breakdown (TDDB) defect of the gate insulation layer 140 may occur.

However, in one or more embodiments, the gate insulation layer 140 may be interposed between the first contact plug 200 and the second gate electrode 170, and the second gate electrode 170 may have the work function that is greater than the work function of the first gate electrode 150. Accordingly, off currents generated in an area where the first contact plug 200, the gate insulation layer 140, and the second gate electrode 170 overlap may be decreased. Additionally, reliability defects of the gate insulation layer in areas where the first contact plug 200, the gate insulation layer 140, and the second gate electrode 170 overlap may be decreased.

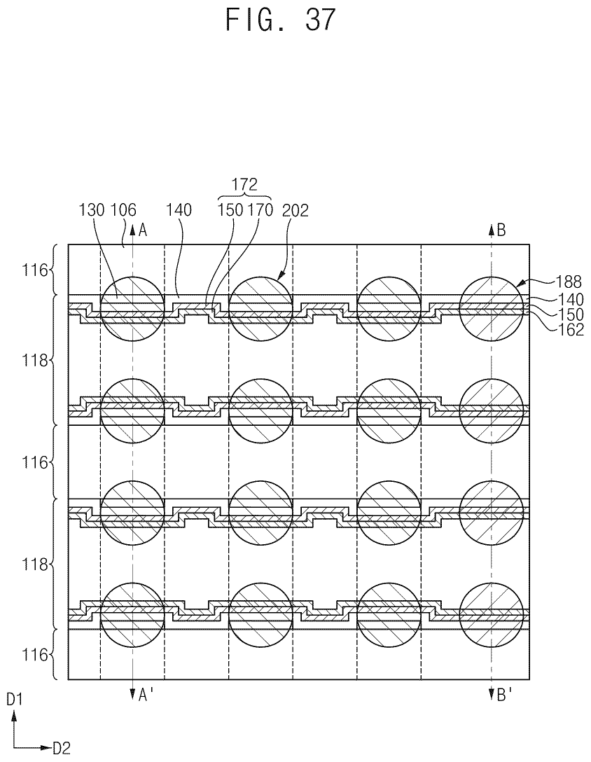

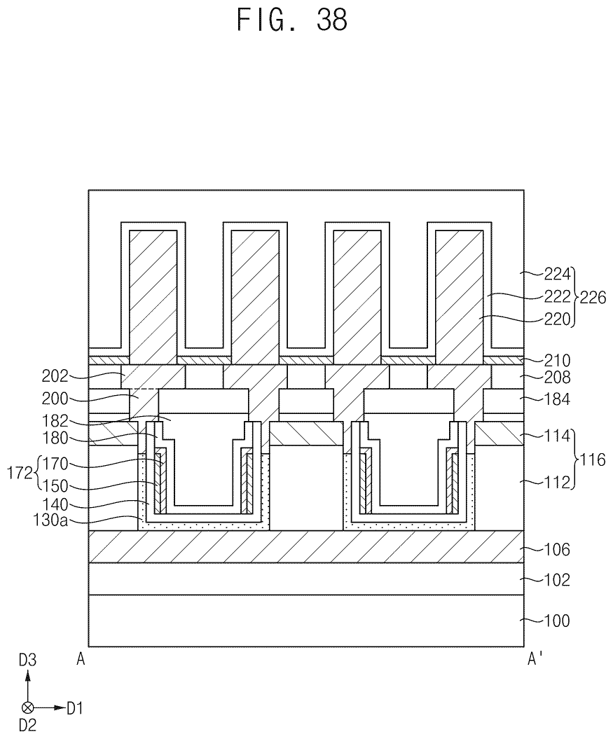

Referring to FIGS. 37 and 38, a second insulation layer may be formed on the first insulation layer 184 and the second and third conductive layer patterns 202 and 206. The second insulation layer may fill a gap between the second conductive layer patterns 202. The second insulation layer may include, e.g., silicon nitride or silicon oxide.

The second insulation layer may be planarized until upper surfaces of the second and third conductive layer patterns 202 and 206 are exposed to form a second insulation pattern 208. The second insulation pattern 208 may be formed in the gap between the second conductive layer patterns 202.

A first etch stop layer 210 may be formed on the second insulation pattern 208. A capacitor 226 may pass through the first etch stop layer 210, and may contact the upper surface of the second conductive layer pattern 202. The capacitor 226 may include a lower electrode 220, a dielectric layer 222, and an upper electrode 224 sequentially stacked. The lower electrode 220 may directly contact an upper surface of the second conductive layer pattern 202. The lower electrode 220 may have a pillar shape. A semiconductor device may be manufactured by above processes.

In one or more embodiments, the gate electrode structure 172 may be formed by stacking the first gate electrode 150 and the second gate electrode 170 in the first direction D1. The second gate electrode 170 may include a conductive material having the work function that is greater than the work function of the first gate electrode 150. The portion of the gate insulation layer 140 may be interposed between the first contact plug 200 and the second gate electrode 170. Accordingly, in the vertical channel transistor, reliability defects of the gate insulation layer occurred in the area where the first contact plug 200, the gate insulation layer 140, and the second gate electrode 170 overlap may be decreased.

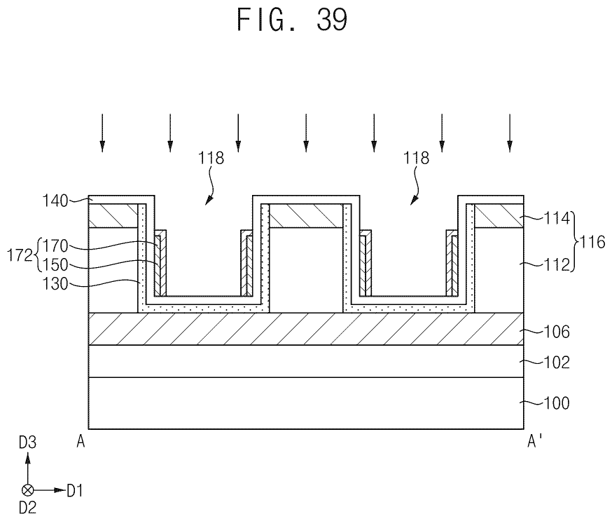

FIG. 39 is a cross-sectional view illustrating a method of manufacturing a semiconductor device according to one or more embodiments.

The method of manufacturing a semiconductor device may be the same as those described with reference to FIGS. 6 to 38, except for some processes for forming a second gate electrode.

First, the process described with reference to FIGS. 6 to 19 may be performed. In the processes, a conductive material whose a work function may be increased by performing a surface treatment process may be deposited to form the first gate electrode layer 142. In one or more embodiments, the first gate electrode layer 142 may include a metal having a work function that may be increased by performing a nitridation process. For example, the first gate electrode layer 142 may include titanium. In this case, the first gate electrode 150 may include titanium.

Thereafter, the processes described with reference to FIGS. 20 to 22 may be performed to form the first gate electrode 150 on the gate insulation layer 140.

Referring to FIG. 39, a surface treatment process of the first gate electrode 150 may be performed to form a second gate electrode 170 on the surface of the first gate electrode 150. The second gate electrode 170 may have a work function that is greater than the work function of the first gate electrode 150.

The surface treatment may include, e.g., nitridation treatment. When the first gate electrode 150 includes titanium, the second gate electrode 170 may include titanium nitride.

Accordingly, the gate electrode structure 172 including the first and second gate electrodes 150 and 170 may be formed.

Thereafter, same processes as those described with reference to FIGS. 29 to 38 may be performed to manufacture the semiconductor device shown in FIGS. 1 and 2.

The vertical channel transistor included in the semiconductor device of one or more embodiments may be used as a selection transistor for various memory devices. The semiconductor devices of one or more embodiments may be used as memories included in electronic products such as mobile devices, memory cards, and computers.

In the semiconductor device according to one or more embodiments, the vertical channel transistor may include the first gate electrode having the first work function and the second gate electrode having the second work function that is greater than the first work function. As the first gate electrode is provided, the vertical channel transistor may have target electrical characteristics. As the second gate electrode is provided, a breakdown and damages of the gate insulation layer between the first contact plug and the second gate electrode may be decreased. Accordingly, reliability defects of the gate insulation layer may be decreased. Therefore, characteristics of the vertical channel transistor in the semiconductor device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a channel pattern on a substrate, the channel pattern comprising channel pattern sidewall portions extending in a first direction that is perpendicular to a surface of the substrate and a channel pattern lower portion connecting lower ends of the channel pattern sidewall portions that face each other in a second direction intersecting the first direction;
a gate insulation layer on surfaces of the channel pattern sidewall portions and the channel pattern lower portion, the gate insulation layer comprising gate insulation layer sidewall portions extending in the first direction and a gate insulation layer lower portion connecting lower ends of the gate insulation layer sidewall portions that face each other in the second direction, the gate insulation layer having an upper surface that is higher than an uppermost surface of the channel pattern;
a first gate electrode on an inner surface of at least one of the gate insulation layer sidewall portions, the first gate electrode having a first work function;
a second gate electrode covering a surface of the first gate electrode, and the second gate electrode having a second work function that is greater than the first work function; and
a first contact plug on the uppermost surface of the channel pattern, the first contact plug contacting an upper portion of the gate insulation layer,
wherein an uppermost surface of the second gate electrode is higher than the uppermost surface of the channel pattern.

2. The semiconductor device of claim 1, wherein the channel pattern comprises an oxide semiconductor.

3. The semiconductor device of claim 1, wherein a height difference between an uppermost surface of the first gate electrode and the uppermost surface of the channel pattern is less than a height difference between the uppermost surface of the second gate electrode and the uppermost surface of the channel pattern.

4. The semiconductor device of claim 3, wherein the uppermost surface of the first gate electrode is coplanar with the uppermost surface of the channel pattern.

5. The semiconductor device of claim 1, wherein a height difference between an uppermost surface of the first gate electrode and the uppermost surface of the channel pattern is less than 5% of a vertical height of the channel pattern.

6. The semiconductor device of claim 1, wherein the first contact plug has a third work function that is equal to or less than the first work function.

7. The semiconductor device of claim 1, wherein the first contact plug comprises an upper portion having a first width and a lower portion having a second width that is less than the first width.

8. The semiconductor device of claim 7, wherein the lower portion of the first contact plug faces the gate insulation layer and the second gate electrode in the second direction.

9. The semiconductor device of claim 1, wherein the gate insulation layer comprises metal oxide having a dielectric constant that is greater than a dielectric constant of silicon nitride, and
wherein the first gate electrode comprises a metal.

10. The semiconductor device of claim 1, wherein the first gate electrode comprises titanium or titanium nitride, and
wherein the second gate electrode comprises Ni or Ru.

11. The semiconductor device of claim 1, further comprising a capacitor on the first contact plug,
wherein the capacitor is connected to the first contact plug.

12. The semiconductor device of claim 1, further comprising a mold insulation structure on an outer surface of the channel pattern,
wherein the mold insulation structure has an upper surface that is higher than the uppermost surface of the channel pattern.

13. A semiconductor device, comprising:
a first conductive layer pattern on a substrate, the first conductive layer pattern extending in a first direction that is parallel to an upper surface of the substrate;
a channel pattern on the first conductive layer pattern, the channel pattern comprising channel pattern sidewall portions extending in a second direction intersecting the first direction and a channel pattern lower portion connecting lower ends of the channel pattern sidewall portions that face each other in the first direction, wherein a lower surface of the channel pattern contacts the first conductive layer pattern;
a gate insulation layer on surfaces of the channel pattern sidewall portions and the channel pattern lower portion, the gate insulation layer comprising gate insulation layer sidewall portions extending in the second direction and a gate insulation layer lower portion connecting lower ends of the gate insulation layer sidewall portions that face each other in the first direction, the gate insulation layer having an upper surface that is higher than an uppermost surface of the channel pattern;
a first gate electrode disposed on an inner surface of at least one of the gate insulation layer sidewall portions, the first gate electrode extending in the third direction intersecting the first direction and parallel to the upper surface of the substrate, the first gate electrode having a first work function;
a second gate electrode covering a surface of the first gate electrode, the second gate electrode extending in the third direction and having a second work function that is greater than the first work function; and
a first contact plug on the uppermost surface of the channel pattern, the first contact plug contacting an upper portion of the gate insulation layer,
wherein a height difference between an uppermost surface of the first gate electrode and the uppermost surface of the channel pattern is less than a height difference between an uppermost surface of the second gate electrode and the uppermost surface of the channel pattern.

14. The semiconductor device of claim 13, wherein the uppermost surface the second gate electrode is higher than the uppermost surface of the channel pattern.

15. The semiconductor device of claim 13, wherein the uppermost surface of the first gate electrode is coplanar with the upper surface of the channel pattern.

16. The semiconductor device of claim 13, wherein the second gate electrode faces the first contact plug in the first direction.

17. The semiconductor device of claim 13, wherein the first contact plug has a third work function that is equal to or less than the first work function.

18. A semiconductor device, comprising:
a channel pattern on a substrate, the channel pattern extending in a first direction perpendicular to a surface of the substrate;
a gate insulation layer on a sidewall of the channel pattern, the gate insulation layer having an upper surface higher than an uppermost surface of the channel pattern;
a first gate electrode on the gate insulation layer, the first gate electrode having a first work function;
a second gate electrode covering a surface of the first gate electrode, the second gate electrode having a second work function that is greater than the first work function; and
a first contact plug on the uppermost surface of the channel pattern, the first contact plug contacting an upper portion of the gate insulation layer;
wherein a lower portion of the first contact plug faces at least a portion of the second gate electrode in a second direction intersecting the first direction.

19. The semiconductor device of claim 18, wherein an uppermost surface of the first gate electrode is coplanar with the uppermost surface of the channel pattern.

20. The semiconductor device of claim 18, wherein the first contact plug has a third work function that is equal to or less than the first work function.
